(19) United States
(12) Patent Application Publication
(10) Pub. No.: US 2023/0260757 A1
(43) Pub. Date: Aug. 17, 2023

(54) PLASMA PROCESSING APPARATUS

(71) Applicant: Tokyo Electron Limited, Tokyo (JP)

(72) Inventors: Hideki SUGIYAMA, Miyagi (JP); Hiroshi IKARI, Miyagi (JP); Nobuyuki NAGAYAMA, Miyagi (JP)

(73) Assignee: Tokyo Electron Limited, Tokyo (JP)

(21) Appl. No.: 18/109,632

(22) Filed: Feb. 14, 2023

(30) Foreign Application Priority Data
Feb. 14, 2022 (JP) 2022-020815

(51) Int. Cl. H01J 37/32

(52) U.S. Cl. CPC H01J 37/3244; H01J 37/32091; H01J 2237/334

(57) ABSTRACT

A plasma processing apparatus includes a plasma processing chamber, a substrate support provided inside the plasma processing chamber and configured to hold a substrate, and a shower head facing the substrate support, wherein the shower head includes a shower plate formed with a gas flow path for discharging a gas, the shower plate includes a base member having a recessed portion, and an embedded member inserted into the recessed portion and bonded to the recessed portion, and the gas flow path includes a first flow path formed in the base member and communicating with the recessed portion, a second flow path formed in the embedded member, and a communication path formed in at least one of the base member and the embedded member and communicating the first flow path and the second flow path.

### CROSS-REFERENCE TO RELATED APPLICATIONS

This application claims priority to Japanese Patent Application No. 2022-020815, filed on Feb. 14, 2022, the entire contents of which are incorporated herein by reference.

### TECHNICAL FIELD

The present disclosure relates to a plasma processing apparatus.

### BACKGROUND

Patent Document 1 discloses a plasma processing apparatus including an upper electrode in which a lower member formed with a gas discharge hole, an intermediate member formed with a communication hole, and an upper member formed with a gas passage hole are laminated.

Further, Patent Document 2 discloses a multilayer silicon electrode plate for plasma etching characterized in that a plurality of thin silicon electrode plates having fine through-holes are laminated to be fixed to a cooling plate having fine through-holes with bolts.

### PRIOR ART DOCUMENTS

### Patent Documents

Patent Document 1: Japanese Patent No. 5336968
Patent Document 2: Japanese Patent No. 3873277

### SUMMARY

In one aspect, the present disclosure provides a plasma processing apparatus that prevents an abnormal discharge.

In order to solve the above-described problem, according to one aspect, there can be provided a plasma processing apparatus including a plasma processing chamber, a substrate support provided inside the plasma processing chamber and configured to hold a substrate, and a shower head facing the substrate support, wherein the shower head includes a shower plate formed with a gas flow path for discharging a gas, the shower plate includes a base member having a recessed portion, and an embedded member inserted into the recessed portion and bonded to the recessed portion, and the gas flow path includes a first flow path formed in the base member and communicating with the recessed portion, a second flow path formed in the embedded member, and a communication path formed in at least one of the base member and the embedded member and communicating the first flow path and the second flow path.

### BRIEF DESCRIPTION OF THE DRAWINGS

FIG. 1 is an example of a view illustrating a configuration example of a capacitively-coupled plasma processing apparatus.

FIG. 2 is an example of a cross-sectional view of a shower plate according to a first embodiment.

FIG. 3A is an example of an upper perspective view of the shower plate, FIG. 3B is an example of a bottom view of the shower plate 132, and FIG. 3C is an example of an enlarged plan view of a flow path.

FIG. 4 is an example of an exploded cross-sectional view of the shower plate.

FIG. 5 is an example of a perspective view illustrating a shape of a flow path formed in the shower plate.

FIG. 6 is an example of a perspective view illustrating another shape of the flow path formed in the shower plate.

FIG. 7 is an example of a perspective view illustrating still another shape of the flow path formed in the shower plate.

FIG. 8 is an example of a perspective view illustrating still another shape of the flow path formed in the shower plate.

FIG. 9 is an example of a cross-sectional view of a shower plate according to a second embodiment.

FIG. 10 is an example of a perspective view illustrating a shape of a flow path formed in the shower plate according to the second embodiment.

FIG. 11 is an example of a cross-sectional view of a shower plate according to a third embodiment.

### DETAILED DESCRIPTION

Hereinafter, various exemplary embodiments will be described in detail with reference to the drawings. Further, like reference numerals will be given to like or corresponding parts throughout the drawings.

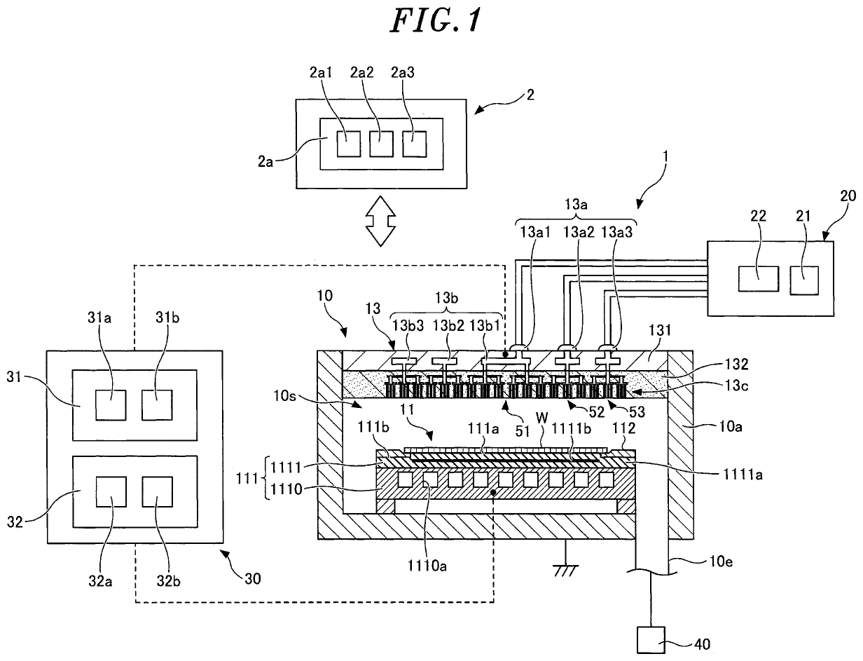

Hereinafter, an example of the configuration example of a plasma processing system will be described. FIG. 1 is an example of a view illustrating a configuration example of a capacitively-coupled plasma processing apparatus.

The plasma processing system includes a capacitively-coupled plasma processing apparatus 1 and a controller 2. The capacitively-coupled plasma processing apparatus 1 includes a plasma processing chamber 10, a gas supply 20, a power source 30, and an exhaust system 40. Further, the plasma processing apparatus 1 includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 has at least one gas supply port for supplying at least one processing gas into the plasma processing space 10s, and at least one gas exhaust port for exhausting the gas from the plasma processing space. The plasma processing chamber 10 is grounded. The shower head 13 and the substrate support 11 are electrically insulated from a housing of the plasma processing chamber 10.

The substrate support 11 includes a main body 111 and a ring assembly 112. The main body portion 111 has a central region 111a for supporting the substrate W and an annular region 111b for supporting the ring assembly 112. The wafer is an example of the substrate W. The annular region 111b of the main body 111 surrounds the central region 111a of the main body 111 in a plan view. The substrate W is disposed on the central region 111a of the main body 111 and the ring assembly 112 is disposed on the annular region 111b of the main body 111 to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. The base 1110 includes a conductive member. The conductive member of the base 1110 functions as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has a central region 111a. In one embodiment, the ceramic member 1111a also has an annular region 111b. Other members that surround the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, at least one RF/DC electrode coupled to a radio frequency (RF) power source 31 and/or a direct current (DC) power source 32 to be described below may be disposed inside the ceramic member 1111a. In this case, at least one RF/DC electrode functions as the lower electrode. In a case where the bias RF signal and/or the DC signal to be described later are supplied to at least one RF/DC electrode, the RF/DC electrode is also referred to as a bias electrode. The conductive member of the base 1110 and at least one RF/DC electrode may function as a plurality of lower electrodes. Further, the electrostatic electrode 1111b may function as the lower electrode. Accordingly, the substrate support 11 includes at least one lower electrode.

The ring assembly 112 includes one or more annular members. In one embodiment, one or more annular members include one or more edge rings and at least one cover ring. The edge ring is formed of a conductive material or an insulating material, and the cover ring is formed of an insulating material.

Further, the substrate support 11 may include a temperature control module configured to adjust at least one of the electrostatic chuck 1111, the ring assembly 112, and the substrate to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed inside the base 1110, and one or more heaters are disposed in the ceramic member 1111a of the electrostatic chuck 1111. Further, the substrate support 11 may include a heat transfer gas supply configured to supply a heat transfer gas to a gap between the rear surface of the substrate W and the central region 111a.

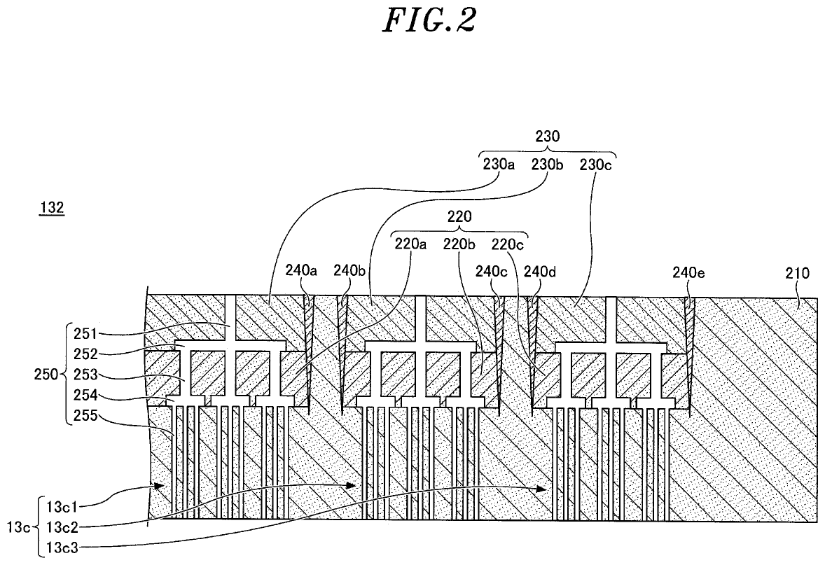

The shower head 13 is configured to introduce at least one processing gas from the gas supply 20 into the plasma processing space 10s. The shower head 13 includes at least one gas supply hole 13a (13a1 to 13a3), at least one gas diffusion chamber 13b (13b1 to 13b3), and a plurality of gas introduction holes 13c (13c1 to 13c3: see FIG. 2). The processing gas supplied to the gas supply port 13a passes through the gas diffusion chamber 13b and is introduced into the plasma processing space 10s from the plurality of gas introduction ports 13c.

Further, the shower head 13 illustrated in FIG. 1 includes a gas introduction portion 51, a gas introduction portion 52, and a gas introduction portion 53. The gas introduction portion 51 introduces a gas into a central region (center region) of the substrate W in the plasma processing chamber 10. The gas introduction portion 52 introduces a gas into a region (intermediate region) outside the gas introduction portion 51. The gas introduction portion 53 introduces a gas into a region (edge region) outside the gas introduction portion 52. The gas introduction portion 51, the gas introduction portion 52, and the gas introduction portion 53 are concentrically disposed.

The gas diffusion chamber 13b includes a gas diffusion chamber 13b1, a gas diffusion chamber 13b2, and a gas diffusion chamber 13b3.

The gas supply hole 13a1 and the plurality of gas introduction holes 13c1 are connected to the gas diffusion chamber 13b1 to allow gases to flow therethrough. The gas introduction portion 51 includes the gas supply hole 13a1, the gas diffusion chamber 13b1, and the plurality of gas introduction holes 13c1. Further, the gas supply hole 13a2 and the plurality of gas introduction holes 13c2 are connected to the gas diffusion chamber 13b2 to allow gases to flow therethrough. The gas introduction portion 52 includes the gas supply hole 13a2, the gas diffusion chamber 13b2, and the plurality of gas introduction holes 13c2. Further, the gas supply hole 13a3 and the plurality of gas introduction holes 13c3 are connected to the gas diffusion chamber 13b3 to allow gases to flow therethrough. The gas introduction portion 53 includes the gas supply hole 13a3, the gas diffusion chamber 13b3, and the plurality of gas introduction holes 13c3.

Further, the shower head 13 includes at least one upper electrode. The gas introduction unit may include, in addition to the shower head 13, one or a plurality of side gas injectors (SGI) that are attached to one or a plurality of openings formed in the sidewall 10a.

Further, the shower head 13 includes a cooling plate 131 and a shower plate 132. The cooling plate 131 is formed of, for example, aluminum and holds the shower plate 132. Further, the cooling plate 131 has a function of cooling the held shower plate 132. Further, the gas diffusion chamber 13b is formed in the cooling plate 131. The shower plate 132 is formed of, for example, Si, SiC, or the like, and includes the gas introduction hole 13c. The cooling plate 131 is an example of a holding plate.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include one or more flow rate modulation devices that modulate or pulse flow rates of at least one processing gas.

The power source 30 includes an RF power source 31 coupled to plasma processing chamber 10 via at least one impedance matching circuit. The RF power source 31 is configured to supply at least one RF signal (RF power) to at least one lower electrode and/or at least one upper electrode.

As a result, plasma is formed from at least one processing gas supplied into the plasma processing space 10s. Accordingly, the RF power source 31 may function as at least a portion of a plasma generator configured to generate plasma from one or more processing gases in the plasma processing chamber 10.

Further, supplying the bias RF signal to at least one lower electrode can generate a bias potential in the substrate W to attract an ionic component in the formed plasma to the substrate W.

In one embodiment, the RF power source 31 includes a first RF generator 31a and a second RF generator 31b. The first RF generator 31a is configured to be coupled to at least one lower electrode and/or at least one upper electrode via at least one impedance matching circuit to generate a source RF signal (source RF power) for plasma generation. In one embodiment, the source RF signal has a frequency in the range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is configured to be coupled to at least one lower electrode via at least one impedance matching circuit to generate the bias RF signal (bias RF power). A frequency of the bias RF signal may be the same as or different from a frequency of the source RF signal. In one embodiment, the bias RF signal has a lower frequency than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or more bias RF signals are supplied to at least one lower electrode. Further, in various embodiments, at least one of the source RF signal and the bias RF signal may be pulsed.

Further, the power source 30 may include a DC power source 32 coupled to the plasma processing chamber 10. The DC power source 32 includes a first DC generator 32a and a second DC generator 32b. In one embodiment, the first DC generator 32a is configured to be connected to at least one lower electrode to generate the first DC signal. The generated first bias DC signal is applied to at least one lower electrode. In one embodiment, the second DC generator 32b is configured to be connected to at least one upper electrode to generate a second DC signal. The generated second DC signal is applied to at least one upper electrode.

In various embodiments, at least one of the first and second DC signals may be pulsed. In this case, the sequence of voltage pulses is applied to at least one lower electrode and/or at least one upper electrode. The voltage pulse may have a pulse waveform of a rectangle, a trapezoid, a triangle or a combination thereof. In one embodiment, a waveform generator for generating a sequence of voltage pulses from the DC signal is connected between the first DC generator 32a and at least one lower electrode. Accordingly, the first DC generator 32a and the waveform generator configure a voltage pulse generator. In a case where the second DC generator 32b and the waveform generator configure the voltage pulse generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

The controller 2 processes computer-executable instructions for instructing the plasma processing apparatus 1 to execute various steps described herein below. The controller 2 may be configured to control the respective components of the plasma processing apparatus 1 to execute the various steps described herein below. In an embodiment, part or all of the controller 2 may be included in the plasma processing apparatus 1. The controller 2 may include a processor 2a1, a storage unit 2a2, and a communication interface 2a3. The controller 2 is implemented by, for example, a computer 2a. The processor 2a1 may be configured to read a program from the storage unit 2a2 and perform various control operations by executing the read program. The program may be stored in advance in the storage unit 2a2, or may be acquired via a medium when necessary. The acquired program is stored in the storage unit 2a2, and is read from the storage unit 2a2 and executed by the processor 2a1. The medium may be various storing media readable by the computer 2a, or may be a communication line connected to the communication interface 2a3. The processor 2a1 may be a Central Processing Unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

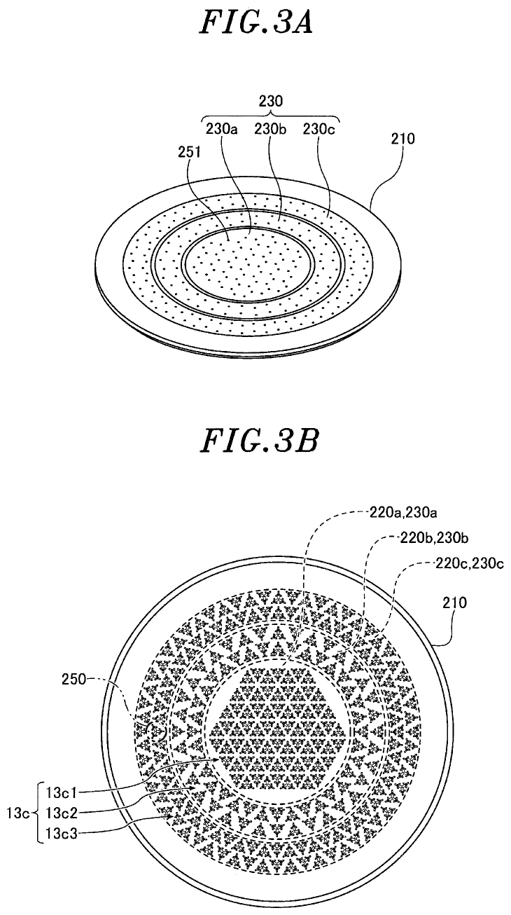

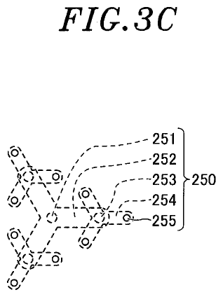

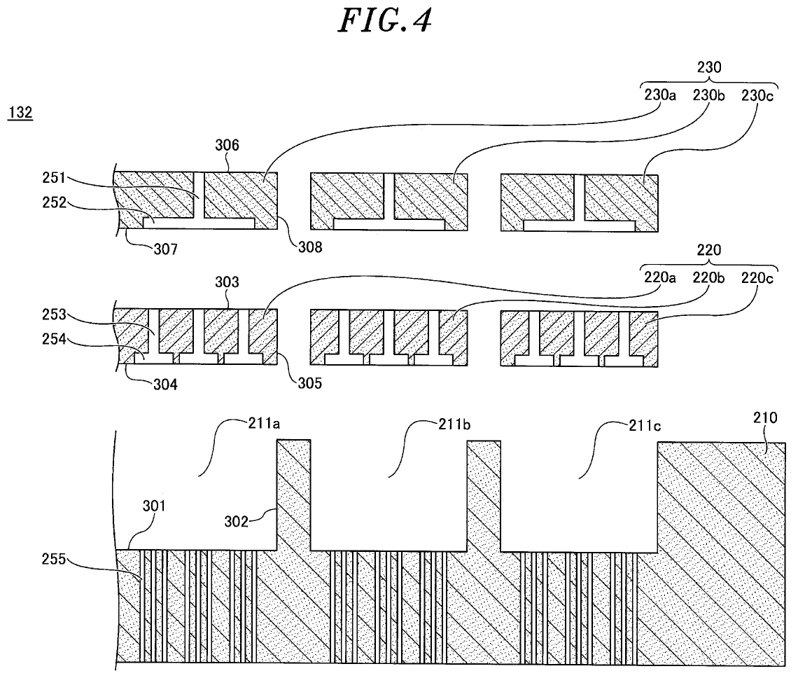

Next, the shower plate 132 in which the gas introduction hole 13c is formed will be described with reference to FIGS. 2 to 5. FIG. 2 is an example of a cross-sectional view of the shower plate 132 according to a first embodiment. FIG. 3A is an example of an upper perspective view of the shower plate 132, FIG. 3B is an example of a bottom view of the shower plate 132, and FIG. 3C is an example of an enlarged plan view of a gas flow path 250. FIG. 4 is an example of an exploded cross-sectional view of the shower plate 132.

As illustrated in FIGS. 2 and 4, the shower plate 132 includes a base member 210 having recessed portions 211a, 211b, and 211c, and embedded members 220 and 230 that are inserted into and bonded to the recessed portions 211a to 211c. The recessed portions 211a to 211c are formed in an upper surface of the base member 210. The recessed portion 211a is formed in an annular shape and coaxially with a central axis of the base member 210. The recessed portion 211b is formed in an annular shape to be coaxial with the central axis of the base member 210 on the outside of the recessed portion 211a in a radial direction. The recessed portion 211c is formed in an annular shape to be coaxial with the central axis of the base member 210 on the outer side of the recessed portion 211b in the radial direction.

An embedded member 220a and an embedded member 230a are laminated and embedded in the recessed portion 211a. The embedded members 220a and 230a are disk-shaped members. The embedded members 220a and 230a are inserted into the recessed portion 211a, a bottom surface 301 of the recessed portion 211a and a lower surface 304 of the embedded member 220a are in contact with each other, and an upper surface 303 of the embedded member 220a and a lower surface 307 of the embedded member 230a are in contact with each other. Further, outer peripheries of the embedded members 220a and 230a are welded to the base member 210 by a welding portion 240a. That is, a side surface 305 of the embedded member 220a and a side surface 308 of the embedded member 230a are bonded to a side surface 302 of the recessed portion 211a of the base member 210 by welding.

Further, the embedded members 220b and 230b are laminated and embedded in the recessed portion 211b. The embedded members 220b and 230b each have an annular shape. The embedded members 220b and 230b are inserted into the recessed portion 211b, inner peripheries of the embedded members 220b and 230b are welded to the base member 210 by a welding portion 240b, and the outer peripheries thereof are welded to the base member 210 by a welding portion 240c.

Likewise, the embedded members 220c and 230c are laminated and embedded in the recessed portion 211c. The embedded members 220c and 230c each have an annular shape. The embedded members 220c and 230c are inserted into the recessed portion 211c, inner peripheries of the embedded members 220c and 230c are welded to the base member 210 by a welding portion 240d, and outer peripheries thereof are welded to the base member 210 by a welding portion 240e.

The base member 210 and the embedded members 220 and 230 are formed of, for example, Si, SiC, or the like. The base member 210 and the embedded members 220 and 230 are preferably formed of the same material. This can reduce or remove a difference in thermal expansion between the base member 210 and the embedded members 220 and 230 when heat of plasma is introduced into the shower plate 132.

Further, the base member 210 and the embedded members 220 and 230 are bonded to each other by welding. Accordingly, when a voltage is applied to the cooling plate 131 from the power source 30, it is possible to prevent a potential difference from being generated between the base member 210 and the embedded members 220 and 230.

A plurality of gas flow paths 250 are formed in the shower plate 132. One gas flow path 250 includes a flow path 251, a branch flow path 252, a flow path 253, a branch flow path 254, and a flow path 255.

A plurality of flow paths 255 are formed in the base member 210 to communicate from the bottom surface 301 of the recessed portion 211a toward a lower surface of the base member 210.

A recessed groove is formed in the lower surface 304 of the embedded member 220a. In a case where the embedded member 220a is inserted into the recessed portion 211a of the base member 210, the branch flow path 254 is formed by the recessed groove formed in the lower surface 304 of the embedded member 220a and the bottom surface 301 of the recessed portion 211a. The branch flow path 254 communicates with the flow path 255. Further, the flow path 253 communicating with a recessed groove serving as the branch flow path 254 is formed in the embedded member 220a toward the lower surface 304 from the upper surface 303. Here, a plurality of (three in the example of FIG. 2) flow paths 253 communicating with the branch flow path 254 are provided in the gas flow path 250, and the number of flow paths 253 is the same as the number of the branch flow paths 254. Further, a plurality of (three in each example of FIG. 2) flow paths 255 communicate with one branch flow path 254. Further, the flow path 255 is an example of a first flow path that is formed in the base member and communicates with a recessed portion included in the base member. Further, the flow path 253 is an example of a second flow path formed in the embedded member. Further, the branch flow path 254 is an example of a communication path that is formed in at least one of the base member and the embedded member and communicates with the first flow path and the second flow path.

A recessed groove is formed in the lower surface 307 of the embedded member 230a. In a case where the embedded member 230a is inserted into the recessed portion 211a of the base member 210, the branch flow path 252 is formed by the recessed groove formed in the lower surface 307 of the embedded member 230a and the upper surface 303 of the embedded member 220a. The branch flow path 252 communicates with the flow path 253. Further, the flow path 251 communicating with the recessed groove serving as the branch flow path 252 is formed in the embedded member 230a toward the lower surface 307 from the upper surface 306. Here, in the gas flow path 250, the number of flow paths 251 communicating with the branch flow path 252 is one and is the same as the number of branch flow paths 252. Further, a plurality of (three in each example of FIG. 2) flow paths 253 communicate with one branch flow path 252.

In this way, the gas flow path 250 is formed which branches from one flow path 251 to the three flow paths 253 via the branch flow path 252 and further branches from each of the flow paths 253 to three flow paths 255 via the branch flow path 254.

Thus, the gas flow path 250 is formed by the embedded members 220a and 230a inserted into the recessed portion 211a. Likewise, the gas flow path 250 is formed by the embedded members 220b and 230b inserted into the recessed portion 211b. Further, the gas flow path 250 is formed by the embedded members 220c and 230c inserted into the recessed portion 211c.

As illustrated in FIGS. 3A to 3C, the shower plate 132 includes a center region where the embedded member 230a (the embedded member 220a) is disposed, an intermediate region where the embedded member 230b (the embedded member 220b) is disposed, and an edge region where the embedded member 230c (the embedded member 220c) is disposed. A plurality of gas flow paths 250 are disposed in each of the center region, the intermediate region, and the edge region. As illustrated in FIG. 3A, a plurality of flow paths 251 are disposed on an upper surface (a surface on the side in contact with the cooling plate 131) of the shower plate 132. Further, as illustrated in FIGS. 3B and 3C, a plurality of flow paths 255 are disposed on a lower surface (a surface on the side of the plasma processing space 10s) of the shower plate 132.

Further, the gas introduction hole 13c1 is formed by the plurality of gas flow paths 250 disposed in the center region of the shower plate 132. Further, the gas introduction hole 13c2 is formed by the plurality of gas flow paths 250 disposed in the intermediate region of the shower plate 132. Further, the gas introduction hole 13c3 is formed by the plurality of gas flow paths 250 disposed in the edge region of the shower plate 132.

In this way, the gas introduction portion 51 introduces the processing gas supplied from the gas supply hole 13a1 into a central region (central region) of the substrate W inside the plasma processing chamber 10 through the gas diffusion chamber 13b1 and the gas introduction hole 13c1 (gas flow path 250). Further, the gas introduction portion 52 introduces the processing gas supplied from the gas supply hole 13a2 into a region (intermediate region) outside the gas introduction portion 51 inside the plasma processing chamber 10 through the gas diffusion chamber 13b2 and the gas introduction hole 13c2 (gas flow path 250). Further, the gas introduction portion 53 introduces the processing gas supplied from the gas supply hole 13a3 into a region (edge region) outside the gas introduction portion 52 inside the plasma processing chamber 10 through the gas diffusion chamber 13b3 and the gas introduction hole 13c3 (gas flow path 250).

Here, the base member 210, the embedded member 220, and the embedded member 230 are welded by the welding portions 240a to 240e, whereby the processing gas supplied to the gas introduction hole 13c1 is prevented from flowing into the other gas introduction holes 13c2 and 13c3. Likewise, the processing gas supplied to the gas introduction hole 13c2 is prevented from flowing into the other gas introduction holes 13c1 and 13c3. Further, the processing gas supplied to the gas introduction hole 13c3 is prevented from flowing into the other gas introduction holes 13c1 and 13c2.

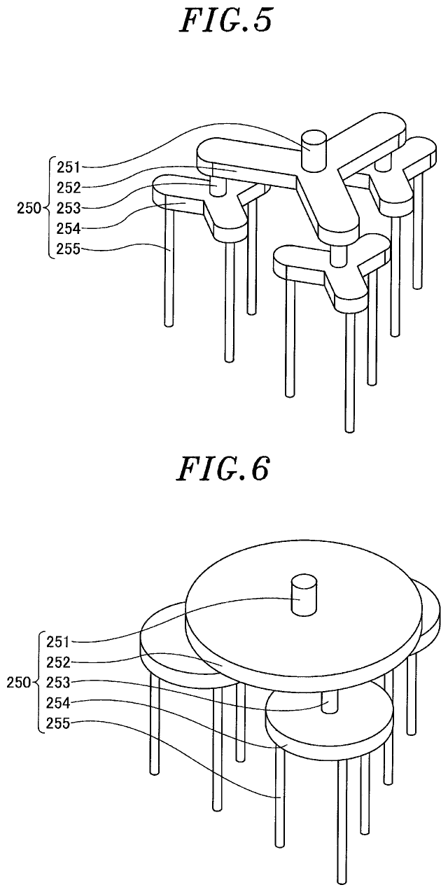

Next, one gas flow path 250 will be further described with reference to FIG. 5. FIG. 5 is an example of a perspective view illustrating a shape of the gas flow path 250 formed in the shower plate 132.

As illustrated in FIG. 5, in the branch flow path 252 in which one of the flow paths 251 branches to three flow paths 253, distances from the flow path 251 to the flow paths 253 are equal to each other. Further, in the branch flow path 254 in which one of the flow paths 253 branches to three flow paths 255, distances from the flow path 253 to the flow paths 255 are equal to each other. In this way, it is configured such that distances in a direction in which the processing gas flows from an inlet of one flow path 251 to an outlet of the nine flow paths 255 are equal to each other.

Here, in the capacitively-coupled plasma processing apparatus 1, RF source power is supplied to either one of the shower head 13 (upper electrode) and the substrate support 11 (lower electrode) disposed vertically in the plasma processing chamber 10, and plasma is generated by discharge generated in the plasma processing space 10s. The gas flow path 250 formed in the shower plate 132 includes the flow paths 251, 253, and 255 extending in an up-down direction, that is, a voltage application direction, and the branch flow paths 252 and 254 extending in the horizontal direction, that is, a direction orthogonal to the voltage application direction.

The flow paths 255 and 253 are not coaxially disposed and are formed to pass through a flow path (the branch flow path 254) extending in a direction orthogonal to a voltage application direction between the flow paths 255 and 253. Likewise, the flow paths 253 and 251 are not coaxially disposed and are formed to pass through a flow path (the branch flow path 252) extending in a direction orthogonal to a voltage application direction between the flow paths 253 and 251.

Here, when a voltage applied to an upper electrode increases, an electric field near the gas introduction hole 13c (the flow path 255) increases, dissociation of the processing gas molecules progresses, and a density of electrons and ions increases. Further, a movement speed of electrons and ions is increased. Accordingly, the processing gas discharged from the gas introduction hole 13c (flow path 255) into the plasma processing space 10s is highly dissociated compared to a case where an application voltage is low, and an abnormal discharge may occur near the gas introduction hole 13c (the flow path 255).

In contrast to this, in the shower plate 132, the gas flow path 250 is formed in the state of a tournament. In this way, it is possible to reduce a distance in a voltage application direction of electrons and ions in the plasma drawn from the plasma processing space 10s into the gas flow path 250. As a result, an average free path of the electrons and ions may be shortened, and thus, it is possible to prevent an abnormal discharge from occurring.

Further, the number of gas holes (the flow paths 251) on an upper surface side of the shower plate 132 can be reduced compared to the number of gas holes (the flow paths 255) on a lower surface side of the shower plate 132. As a result, it is possible to increase a heat transfer region between the shower plate 132 and the cooling plate 131.

Further, by increasing the number of flow paths 255 on a downstream side rather than the flow paths 251 on an upstream side, gas pressures in the flow paths 255 on a lower surface side of the shower plate 132 can be reduced. In this way, it is possible to further prevent an abnormal discharge from occurring.

Further, the shower plate 132 can prevent a potential difference from being generated between the base member 210, the embedded member 220, and the embedded member 230. That is, it is possible to prevent an abnormal discharge from occurring due to the potential difference between the base member 210 and the embedded member 220. Further, it is possible to prevent an abnormal discharge from occurring due to the potential difference between the embedded member 220 and the embedded member 230.

A shape of the gas flow path 250 formed in the shower plate 132 is not limited to the shape illustrated in FIG. 5.

FIG. 6 is an example of a perspective view illustrating another shape of the gas flow path 250 formed in the shower plate 132. As illustrated in FIG. 6, a shape of the branch flow path 252 branching from the flow path 251 toward the three flow paths 253 may be formed in a disk shape. Further, as illustrated in FIG. 6, a shape of the branch flow path 254 branching from the flow path 253 toward the three flow paths 255 may be formed in a disk shape.

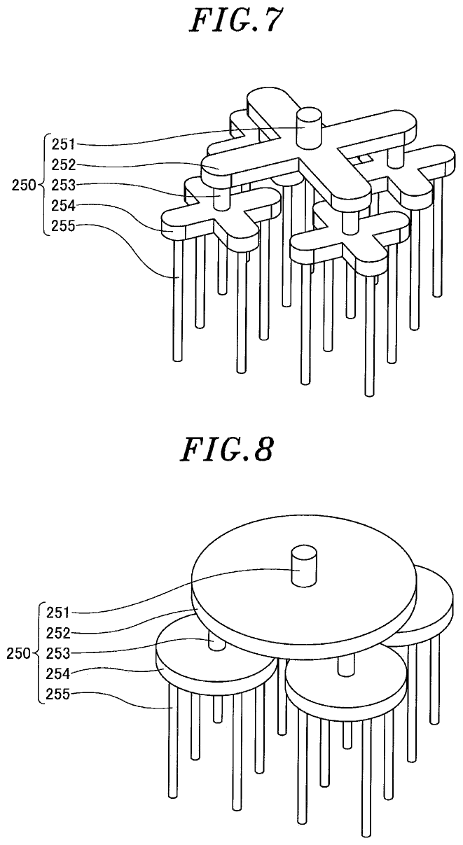

FIG. 7 is an example of a perspective view illustrating still another shape of the gas flow path 250 formed in the shower plate 132. As illustrated in FIG. 7, a shape of the branch flow path 252 branching from the flow path 251 toward the four flow paths 253 may be formed in a cross shape. Further, as illustrated in FIG. 7, a shape of the branch flow path 254 branching from the flow path 253 toward the four flow paths 255 may be a cross shape.

FIG. 8 is an example of a perspective view illustrating still another shape of the gas flow path 250 formed in the shower plate 132. As illustrated in FIG. 8, a shape of the branch flow path 252 branching from the flow path 251 toward the four flow paths 253 may have a disk shape. Further, as illustrated in FIG. 8, a shape of the branch flow path 254 branching from the flow path 253 toward the four flow paths 255 may be a disk shape.

Further, described is a case in which the number of branches of the branch flow paths 252 and 254 is 3 or 4, which may be 2 or 5 or more, though the present disclosure is not limited thereto.

Further, the branch flow paths 252 and 254 may form horizontal flow paths without branched flow paths. In this way, abnormal discharge can be reduced by shortening an average free path of electrons and ions in a voltage application direction (up-down direction).

Further, described is a case such that a recessed groove is formed in the lower surface 307 of the embedded member 230a, and that the branch flow path 252 is formed by the recessed groove formed in the lower surface 307 of the embedded member 230a and the upper surface 303 of the embedded member 220a, though the present disclosure is not limited thereto. A configuration may be provided such that a recessed groove is formed in the upper surface 303 of the embedded member 220a, and that the branch flow path 252 is formed by the lower surface 307 of the embedded member 230a and the recessed groove formed in the upper surface 303 of the embedded member 220a. Further, a configuration may be provided such that a recessed groove is formed in the lower surface 307 of the embedded member 230a and the upper surface 303 of the embedded member 220a, and that the branch flow path 252 is formed by the recessed groove formed in the lower surface 307 of the embedded member 230a and the recessed groove formed in the upper surface 303 of the embedded member 220a.

Likewise, described is a case such that a recessed groove is formed in the lower surface 304 of the embedded member 220a, and that the branch flow path 254 is formed by the recessed groove formed in the lower surface 304 of the embedded member 220a and the bottom surface 301 of the recessed portion 211a, though the present disclosure is not limited thereto. A configuration may be provided such that a recessed groove is formed in the bottom surface 301 of the recessed portion 211a, and that the branch flow path 254 is formed by the lower surface 304 of the embedded member 220a and the recessed groove formed in the bottom surface 301 of the recessed portion 211a. Further, a configuration may be provided such that recessed grooves are formed in the lower surface 304 of the embedded member 220a and the bottom surface 301 of the recessed portion 211a, and that the branch flow path 254 is formed by the recessed groove formed in the lower surface 304 of the embedded member 220a and the recessed groove formed in the bottom surface 301 of the recessed portion 211a.

The base member 210 and the embedded members 220 and 230 are described as being bonded to each other by welding, though the present disclosure is not limited thereto. A configuration may be provided such that the base member 210 and the embedded members 220 and 230 are bonded to each other by adhesion of a conductive adhesive. Even in this case, it is possible to prevent a potential difference from being generated between the base member 210 and the embedded members 220 and 230 when a voltage is applied from the power source 30 to the cooling plate 131. That is, it is possible to prevent an abnormal discharge from occurring due to the potential difference between the base member 210 and the embedded member 220. Further, it is possible to prevent an abnormal discharge from occurring due to the potential difference between the embedded member 220 and the embedded member 230.

Further, described is a case in which the shower head 13 includes the three gas supply holes 13a (13a1 to 13a3) and is partitioned into the three gas introduction portions 51 to 53, though the shower head 13 is not limited thereto. The number of partitions of the shower head 13 may be one, two, or four or more.

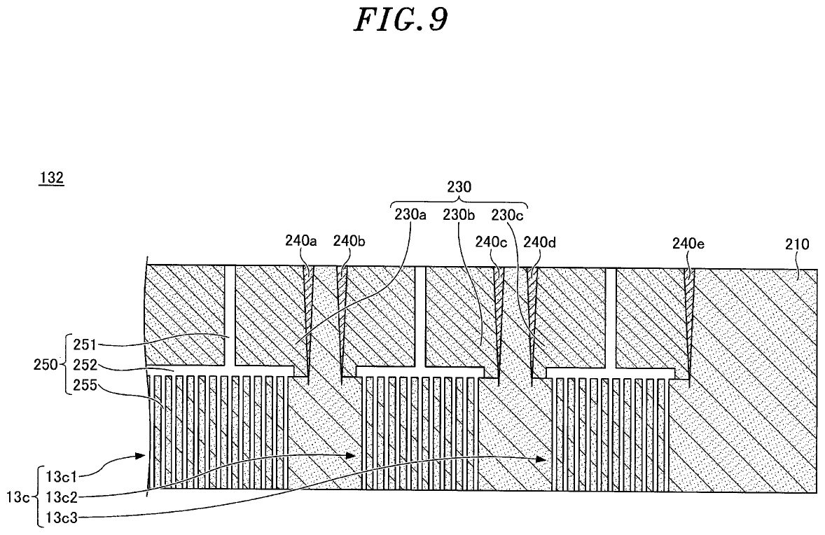

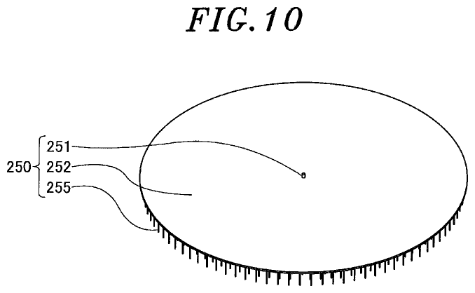

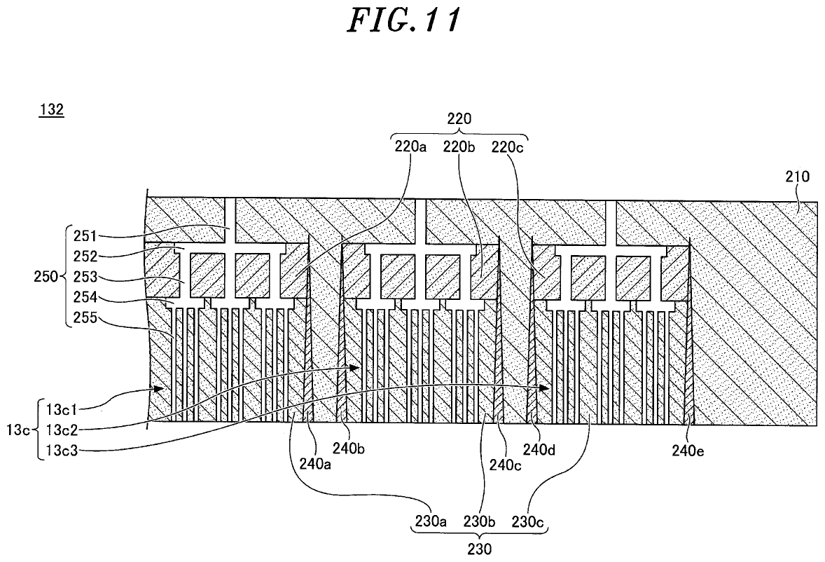

FIG. 9 is an example of a cross-sectional view of a shower plate 132 according to a second embodiment. FIG. 10 is an example of a perspective view illustrating a shape of a gas flow path 250 formed in the shower plate 132 according to the second embodiment.

As illustrated in FIG. 9, an embedded member 230 inserted into a recessed portion of a base member 210 may be a single layer. A plurality of gas flow paths 250 are formed in the shower plate 132. As illustrated in FIGS. 9 and 10, the gas flow path 250 includes a flow path 251, a branch flow path 252, and a plurality of flow paths 255.

A plurality of flow paths 255 are formed in the base member 210 to communicate from a bottom surface of a recessed portion, into which an embedded member 230a is inserted, toward a lower surface of the base member 210.

A recessed groove is formed in a lower surface of the embedded member 230a. In a case where the embedded member 230a is inserted into a recessed portion of the base member 210, a recessed groove formed in a lower surface of the embedded member 230a and a bottom surface of the recessed portion form the branch flow path 252. The branch flow path 252 communicates with the flow path 255. Further, the flow path 251 communicating with a recessed groove serving as the branch flow path 252 is formed in the embedded member 230a from an upper surface toward a lower surface. Here, in the gas flow path 250, the number of flow paths 251 communicating with the branch flow path 252 is one and is the same as the number of branch flow paths 252. Further, a plurality of flow paths 255 communicate with one branch flow path 252.

In this way, the gas flow path 250 branching from one flow path 251 to the plurality of flow paths 255 via the branch flow path 252 is formed.

Thus, the gas flow path 250 is formed by the embedded member 230a inserted into the recessed portion of the base member 210. Likewise, the gas flow path 250 is formed by an embedded member 230b inserted into the recessed portion of the base member 210. Further, the gas flow path 250 is formed by an embedded member 230c inserted into the recessed portion of the base member 210.

Described as examples are a case in which the embedded member inserted into the recessed portion of the base member 210 has one layer (see FIG. 9) and a case in which the embedded member inserted into the recessed portion of the base member 210 has two layers (see FIG. 2), though the present disclosure is not limited thereto, and the embedded member may have three or more layers.

FIG. 11 is an example of a cross-sectional view of a shower plate 132 according to a third embodiment.

In the shower plate 132 illustrated in FIG. 11, a recessed portion may be formed on a lower surface side of the base member 210, and embedded members 220 and 230 may be disposed in the recessed portion to be bonded thereto by welding or adhesive bonding. A plurality of gas flow paths 250 are formed in the shower plate 132. The gas flow path 250 includes a flow path 251, a branch flow path 252, a flow path 253, a branch flow path 254, and a flow path 255.

The flow path 251 communicating from a top surface of the recessed portion toward an upper surface of the base member 210 is formed in the base member 210.

A recessed groove is formed in an upper surface of an embedded member 220a. In a case where the embedded member 220a is inserted into the recessed portion of the base member 210, a recessed groove formed in an upper surface of the embedded member 220a and a top surface of the recessed portion form the branch flow path 252. The branch flow path 252 communicates with the flow path 251. Further, the flow path 253 communicating with the recessed groove serving as the branch flow path 252 is formed in the embedded member 220a from the upper surface toward the lower surface.

A recessed groove is formed in the upper surface of an embedded member 230a. In a case where the embedded member 230a is inserted into a recessed portion of the base member 210, the recessed groove formed in an upper surface of the embedded member 230a and a lower surface of the embedded member 220a form the branch flow path 254. The branch flow path 254 communicates with the flow path 253. Further, the flow path 255 communicating with the recessed groove serving as the branch flow path 254 is formed in the embedded member 230a toward the lower surface from the upper surface.

In this way, the gas flow path 250 is formed which branches from one flow path 251 to the three flow paths 253 via the branch flow path 252 and further branches from each of the flow paths 253 to three flow paths 255 via the branch flow path 254.

In this way, the gas flow path 250 is formed by the embedded members 220a and 230a inserted into the recessed portion of the base member 210. Likewise, the gas flow path 250 is formed by the embedded members 220b and 230b inserted into the recessed portion of the base member 210. Further, the gas flow path 250 is formed by the embedded members 220c and 230c inserted into the recessed portion of the base member 210.

Although embodiments and the like of a plasma processing system are described above, the present disclosure is not limited to the above-described embodiments and the like, and various modifications and improvements are possible within the scope of the present disclosure described in the claims.

1. A plasma processing apparatus comprising:
a plasma processing chamber;
a substrate support provided inside the plasma processing chamber and configured to hold a substrate; and
a shower head facing the substrate support,
wherein the shower head includes a shower plate formed with a gas flow path for discharging a gas,
the shower plate includes a base member having a recessed portion, and an embedded member inserted into the recessed portion and bonded to the recessed portion, and
the gas flow path includes a first flow path formed in the base member and communicating with the recessed portion, a second flow path formed in the embedded member, and a communication path formed in at least one of the base member and the embedded member and communicating the first flow path and the second flow path.

2. The plasma processing apparatus according to claim 1, wherein the first flow path and the second flow path are disposed non-coaxially.

3. The plasma processing apparatus according to claim 1, wherein the base member and the embedded member are bonded to each other by welding or by adhesion of a conductive adhesive.

4. The plasma processing apparatus according to claim 1, wherein the base member and the embedded member are formed of Si or SiC.

5. The plasma processing apparatus according to claim 4, wherein the base member and the embedded member are formed of the same material.

6. The plasma processing apparatus according to claim 1, wherein a plurality of the embedded members are laminated and bonded to the recessed portion of the base member, and
the gas flow path is formed between the laminated embedded members.

7. The plasma processing apparatus according to claim 1, wherein the shower head further includes a holding plate that holds the shower plate, and a voltage from a power source is applied to the holding plate.
